(19) United States
(12) Patent Application Publication
(10) Pub. No.: US 2008/0094030 A1
(43) Pub. Date: Apr. 24, 2008

(54) LIGHT-WEIGHT PACKAGE FOR LITHIUM BATTERY

(75) Inventor: RAY LUNDY, BEND, OR (US)

Correspondence Address: PEDERSEN & COMPANY, PLLC, P.O. BOX 2666, BOISE, ID, 83701, US

(73) Assignee: BELLATRIX SYTEMS, INC., Bend, OR (US)

(21) Appl. No.: 11/869,745

(22) Filed: Oct. 9, 2007

Related U.S. Application Data
(60) Provisional application No. 60/850,087, filed on Oct. 6, 2006.

(51) Int. Cl. H02J 7/00; G01R 31/36

(52) U.S. Cl. 320/126

(57) ABSTRACT

A monitor and control circuit optimizes batteries' efficiency, monitors and provides for variable loads, and protects batteries from interacting negatively with each other. For example, the monitor and control circuit monitors the voltage and output of each of three AA-sized lithium batteries connected in parallel, connecting batteries to and disconnecting them from the load with a timed control function to maximize battery efficiency and safety.

This application claims priority of my prior, co-pending provisional patent application, Ser. 60/850,087 filed on Oct. 6, 2006, entitled “Light Weight Package for Lithium Battery,” which is incorporated herein by reference.

### BACKGROUND OF THE INVENTION

1. Field of the Invention

An electronic lithium battery monitor and control circuit is created to allow multiple batteries to be connected in a parallel fashion. Via this method, three (3) standard size-AA batteries are chosen and combined to maximize available energy while providing a lithium weight content of less than or equal to 2.0 grams acceptable to air shipping regulations. The AA-sized batteries are specially manufactured to each contain about ⅔ gram or less lithium as defined in the applicable IATA (International Air Transport Association) air shipping regulations.

2. Related Art

New regulations introduced by world authorities have restricted the total amount of lithium that may be contained in batteries that are shipped via air. Batteries are conventionally provided in a number of different standard battery sizes and energies, none of which take into account the new shipping regulations. The need is for a lithium battery solution that provides optimum battery energy while meeting the relatively new air shipping regulations.

Connecting batteries together in parallel can result in one battery damaging or reducing the energy of others. Additionally, lithium thionyl chloride batteries must also have enough current drawn from them to avoid “passivation”, or the inability of the battery to deliver higher currents. Traditional methods of connecting batteries in parallel and yet protecting them from each other use diodes or traditional bipolar transistor circuits. These waste energy in the switching components.

### SUMMARY OF THE INVENTION

The monitor and control of the present invention circuit optimizes the batteries' efficiency, monitors and provides for variable loads, and protects the batteries from interacting negatively with each other.

The described monitor and control circuit of the present invention is comprised of the following structure, and acts in the following manner, to address these needs:

When the load is idle and very little current is being drawn, the circuit switches on one high efficiency FET transistor per battery on a regular basis, each battery in turn, insuring that each battery is receiving the total current load. This insures that battery passivation is reduced, the energy draw by the load is evenly distributed between the batteries, and the batteries are isolated from each other. This minimizes periods of very low current draw, when battery voltages are most likely unequal, thereby minimizing the possibility of negative interactions.

While switching between batteries, the circuit monitors the output of each battery so as to detect the application of a load. A load large enough to require the parallel connection of multiple batteries to meet the need, and to insure the safe connection of more than one battery together in parallel, prompts a response. Loads large enough to reduce the voltage of all batteries applied allow a safe parallel connection. Upon detecting the load condition, the circuit connects more than one battery to the load by turning on multiple high efficiency FET transistors at the same time.

During the condition of having multiple batteries connected to the load, the circuit monitors the battery voltage on a regular interval to detect the removal of the load. If the load is removed, the circuit returns to selecting one battery at a time.

Additionally, the circuit may monitor aid record the absolute voltage value of each battery and remove a selected battery from the circuit if the battery fails to meet a required absolute value.

Additionally, the circuit may monitor aid record the relative voltage value of each battery compared to the others, and remove a selected battery from the circuit if the battery fails to meet a required relative value.

At no time are batteries left connected together for long enough to cause a negative interaction between them.

### BRIEF DESCRIPTION OF THE DRAWINGS

FIG. 1 is an electrical schematic diagram of a circuit for one embodiment of the present invention with 3 (three) AA lithium batteries.

FIG. 2 is a top view of a physical embodiment of one version of the subject invention.

FIG. 3 is a top view of the embodiment of FIG. 2 opened up to display the arrangement of batteries within the package.

FIG. 4 is a side view of the embodiment of FIGS. 2 and 3.

FIG. 5 is a top, perspective view of the embodiment of FIGS. 2, 3, and 4.

FIG. 6 is a top, perspective fully-exploded view of the embodiment of FIGS. 2-5.

FIG. 7 is a top, perspective partially-assembled view of the embodiment of FIGS. 2-6.

### DETAILED DESCRIPTION OF THE INVENTION

### Circuit Description

In One Embodiment:

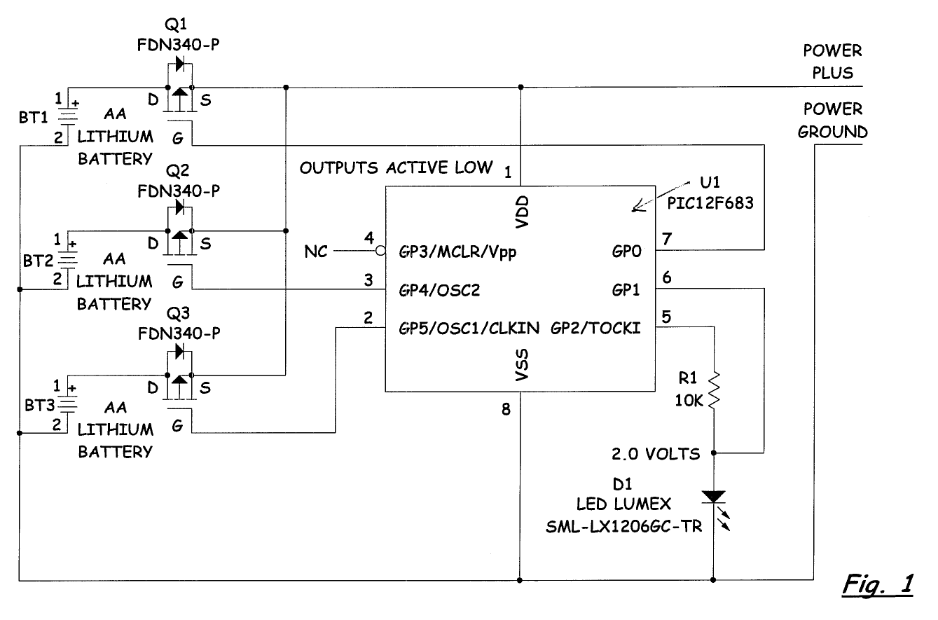

Referring to FIG. 1, there is depicted the microprocessor U1, for example a Microchip PIC12F683, which controls three N Channel FET switches labeled Q1 through Q3. Three AA lithium thionyl chloride batteries are connected, one to each FET switch. R1, a 10 K ohm resistor and D1, a 2 volt LED, act as a reference voltage for the microprocessor.

The three AA batteries have total content matching the maximum lithium allowed under air shipment regulation, yet supply nearly the energy of a standard C cell and roughly match the current capability of a standard D cell, both of which fail to meet regulations for safe air shipment because they both contain more than 2.0 grams of lithium as defined by the regulatons. This combination of the present invention, then, maximizes energy delivery and capability at the air shipment 2.0 gram lithium weight limit.

“Power Plus” is connected to U1 at VDD to both power it and to provide a reference for the analog to digital converter contained in the chip. The 2 volt reference D1 is applied to an input of the analog to digital converter. By comparing the two voltages, at VDD and at D1, U1 is able to determine the voltage of each, any or all batteries as they are switched oil by each FET and applied to VDD.

U1 output GP2 is used to switch on the voltage for R1 and D1 only when an analog to digital conversion is required, thus increasing efficiency.

The output voltage of the circuit is applied to the load through “power Plus” and “Power Ground”.

### Firmware Description

In One Embodiment:

The software in U1 switches each FET on for one second in turn, leaving a few microsecond overlap to insure continuous power to the load.

Every 45 milliseconds, for example, the D1 reference is turned on, a voltage measurement is taken and is stored.

If the new voltage measurement is approximately 0.1 volts lower, for example, than the last measurement, switching between batteries is ceased and all battery FETs are turned on.

After all batteries are turned on, every 500 milliseconds, for example, two batteries are turned back off while the last battery to be active alone is left on. A new voltage measurement is taken and is compared to the measurement before the load was introduced.

If the new voltage measurement shows the voltage returned to within 0.1 volts of the previous reading, for example, the software returns to switching between batteries. If not, all batteries are left connected.

If the new voltage measurement of the battery is less or equal to a stored voltage representing the lowest allowable voltage of the battery of the driven circuit, for example, at 3.0 volts when the system normally runs at about 3.6 volts, and the battery is shown to not be under heavy load, the battery FET for the low voltage battery is permanently turned off.

If the new voltage measurement of the battery is equal to or less than 0.2 volts lower, for example, than the stored voltage representing any other battery, and the battery is shown not to be under heavy load, the battery FET for the lower voltage battery is permanently turned off.

### Hardware Description

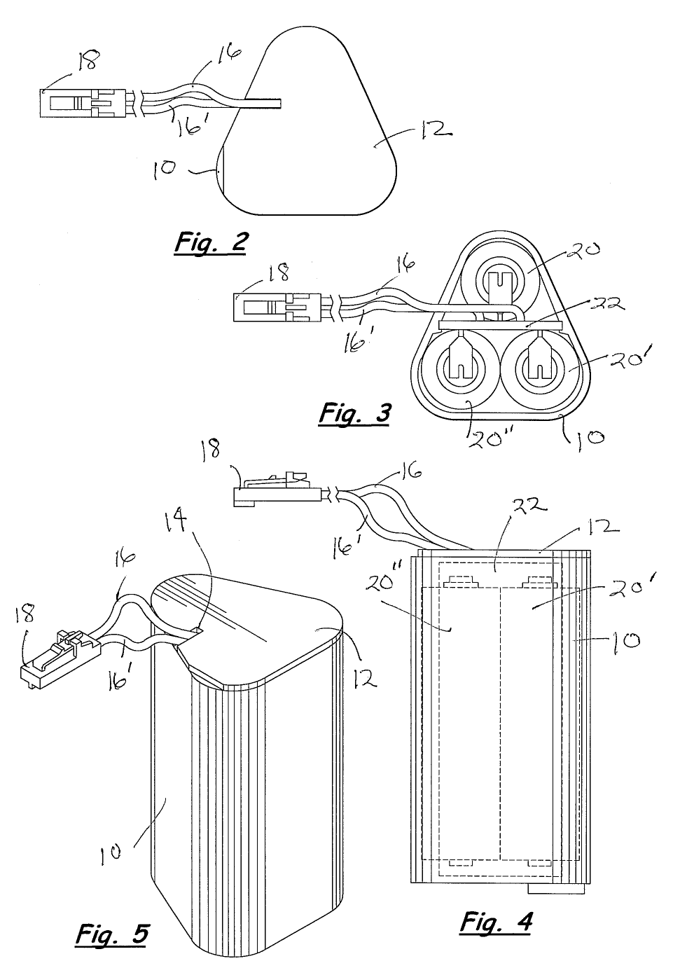

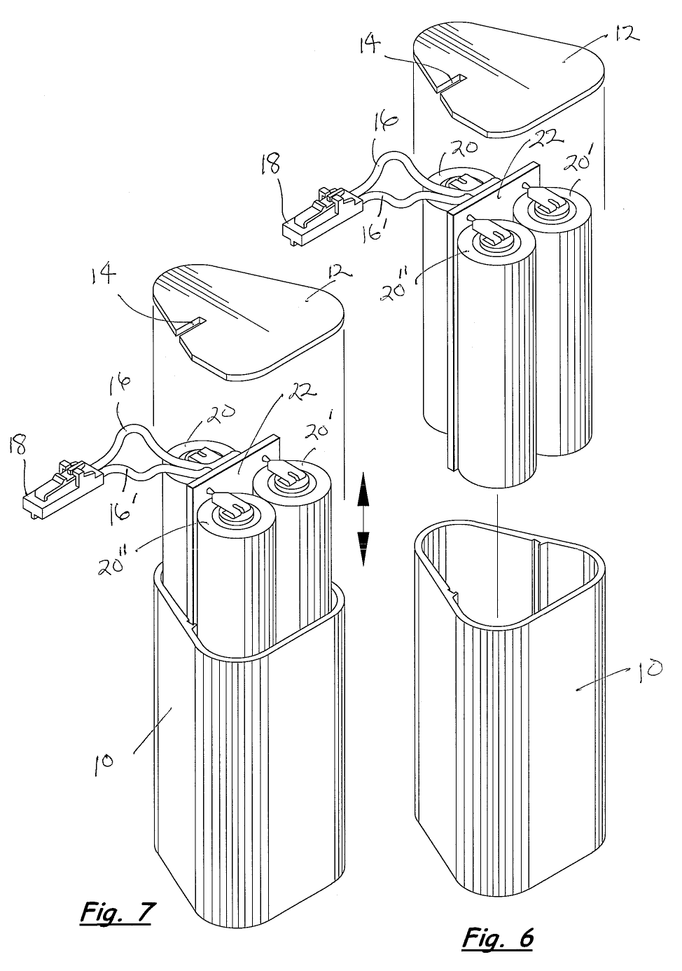

One embodiment of the present invention is depicted in different views in FIGS. 2-7. The battery package has a housing 10 with a top 12. Preferably, the housing 10 and top 12 are made of plastic, non-conductive material. Extending through a slot 14 in top 12 are electrical power lines 16 and 16′ that correspond to “Power Plus” and “Power Ground” in FIG. 1. Power lines 16 and 16′ connect to standard power plug 18. Plug 18 fits into standard power receptacles to, for example, portable digital devices. Top 12 fits securely onto housing 10, and, preferably is conveniently removably detached therefrom. Inside housing 10 is a set of three (3) AA-sized battery packages 20, 20′ and 20″, they being connected to monitor and control circuit board 22, which board is also attached to the power lines 16 and 16′.

Battery packages 20, 20′ and 20″ are standard-AA-sized, but, in the preferred embodiment, provided with less than or equal to ⅔ grams each of lithium as it is defined in the relevant IATA regulations. This way, the stun of the lithium content for the three (3) batteries is less than or equal to 2.0 grams, the upper limit for air shipping of the entire battery system under the current regulations. The battery packages may be manufactured by conventional techniques.

Control circuit board 22 embodies the monitor and control circuit shown in FIG. 1. Circuit board 22 may be manufactured by conventional techniques.

Although this invention has been described above with reference to particular means, materials, and embodiments, it is to be understood that the invention is not limited to these disclosed particulars, but extends instead to all equivalents within the scope of the following claims.

1. A set of battery packages comprising:
a plurality of battery packages being arranged electrically in parallel; and
each of said battery packages being electrically connected to a monitor and control circuit comprising:
a switch for each battery; and
a microprocessor containing software for switching the batteries oil and off the circuit singly in turn, or sequentially a plurality of different batteries at the same time together, or all together, while at the same time, measuring the voltage of each, any combination of, or all of the batteries as they are switched oil.

2. A set of battery packages comprising:
a plurality of standard size, individual AA battery packages being arranged electrically in parallel;
each of the individual AA battery packages comprising less of the lithium content as defined in International Air Transport Association (IATA) regulations, so that the sum of the individual AA battery packages' lithium content is less than or equal to 2.0 grams; and
each of the individual AA battery packages being electrically connected to a monitor and control circuit comprising:
a plurality of switches, one switch for each battery; and
a microprocessor containing software for switching the batteries on and off the circuit singly in turn, or sequentially a plurality of different batteries at the same time together, or all together while at the same time measuring the voltage of each, any combination of, or all batteries as they are switched on.

3. The set of battery packages of claim 2 wherein there are three individual AA-sized battery packages.

4. The set of battery packages of claim 3 wherein each battery package comprises less than about ⅔ grams lithium content.
